(19) United States
(12) Patent Application Publication
(10) Pub. No.: US 2020/0343004 A1
(43) Pub. Date: Oct. 29, 2020

(54) LOW PRESSURE PLASMA MODE

(71) Applicant: Tokamak Energy Ltd., Oxfordshire (GB)

(72) Inventors: Christian Bradley, Abingdon, Oxfordshire (GB); Damian Lockley, Abingdon, Oxfordshire (GB); Mikhail Gryaznevich, Abingdon, Oxfordshire (GB); Vladimir Shevchenko, Abingdon, Oxfordshire (GB)

(21) Appl. No.: 16/757,060

(22) PCT Filed: Oct. 18, 2018
(86) PCT No.: PCT/GB2018/053016

§ 371 Date: Apr. 17, 2020

(30) Foreign Application Priority Data
Oct. 20, 2017 (GB) 1717225.5

(51) Int. Cl. G21B 1/05; H05H 1/03; H01J 37/32

(52) U.S. Cl. CPC G21B 1/057; H05H 1/03; H05H 2001/4697; H01J 37/32862; H01J 37/32816

(57) ABSTRACT

A helium plasma characterised by an emission spectrum dominated by the 1s3p ¹P₁ to 1s2 ¹S₀ 501.5 nm transmission line, and a pressure less than 5×10⁻³ mbar. Methods and apparatus for igniting the plasma, and for using the plasma for pre-ionisation and glow discharge cleaning are also disclosed.

### FIELD OF THE INVENTION

The present invention relates to plasmas and plasma chambers. In particular, the invention relates to a plasma mode, the ignition of such a mode, and the use of such a mode for glow discharge cleaning and pre-ionisation.

### BACKGROUND

The challenge of producing fusion power is hugely complex. In addition to the fundamental challenge of confining and sustaining a fusion reaction, a vast number of engineering problems arise during the development and operation of fusion devices.

The tokamak is a well-known class of fusion device which uses magnetic fields to confine high temperature plasma within a toroidal reactor vessel. The formation of the plasma must be carefully controlled in order for the tokamak to operate safely and efficiently.

In order to avoid contamination of the plasma during operation, the walls of the plasma chamber must be cleaned. Otherwise, high atomic number elements from the walls may be sputtered into the fusion plasma, causing the temperature of the plasma to be reduced. This cleaning is typically done by glow discharge cleaning (GDC). GDC is performed by generating a plasma within the plasma chamber using DC biased electrodes to generate a potential across the plasma. This plasma sputters contaminants from the chamber walls, which can then be pumped out of the chamber with the GDC plasma.

GDC is typically performed with a helium plasma, at pressures above the high 10⁻³ mbar range. Argon, hydrogen and other gases may also be used. At these high pressures, the plasma will tend to arc, which can extinguish the plasma, and the high localised current can also damage components within the chamber. The tendency for the plasma to arc is particularly pronounced in the high 10⁻³ mbar range, and the plasma cannot be maintained below this range.

The initial stage of a tokamak discharge may be divided into three phases: breakdown, plasma formation and current rise. Generally, these phenomena are all achieved using an ohmic transformer to apply a toroidal electric field. These phases directly affect the ultimate properties of the plasma in the light of the production of runaway electrons, impurity, equilibrium, stability, etc. To optimise these plasma parameters, it is, therefore, necessary to optimise these initial phases. As is well known, a long pre-breakdown phase with a high loop voltage not only produces a large quantity of runaway electrons (which will influence the character of the discharge later), but also consumes a lot of valuable volt-seconds and potentially can generate harmful hard X-rays. Many tokamaks employ special pre-ionisation systems in order to control the breakdown of prefilled gases.

Pre-ionisation can be achieved by various means, but one common procedure is to inject electrons into the plasma chamber using an electron source such as a biased filament (i.e. a negatively charged hot filament which will expel thermionic electrons). However, the electrons expelled by the filament will tend to ground on the nearest structure (generally the support structures of the plasma chamber) rather than reaching the plasma itself, and the material of the filament can evaporate during use, contaminating the plasma.

### SUMMARY

According to a first aspect of the present invention, there is provided a helium plasma characterised by an emission spectrum dominated by the 1s3p ¹P₁ to 1s2s ¹S₀ 501.5 nm transmission line, and a pressure less than 5×10⁻³ mbar.

According to a second aspect, there is provided a plasma vessel. The plasma vessel comprises a DC voltage source, a vacuum system, and a helium plasma according to the first aspect. The DC voltage source is configured to provide a voltage across a plasma within the chamber. The vacuum system is configured to maintain the pressure of the interior of the plasma vessel at less than 5×10⁻³ mbar.

According to a third aspect, there is provided a method of forming a glow discharge plasma within a plasma vessel. A gas is provided within the plasma vessel at a pressure less than 5×10⁻³ mbar. A glow discharge plasma is formed from the gas by applying a DC potential across the gas and using an electron source to supply electrons to the gas.

According to a fourth aspect, there is provided a method of glow discharge cleaning a plasma vessel. A glow discharge plasma is formed within the plasma vessel by the method of the first aspect, and the DC voltage is maintained for a duration of the cleaning.

According to a fifth aspect, there is provided a method of pre-ionisation in a fusion reactor comprising a plasma vessel. A glow discharge plasma is formed in the plasma vessel by the method of the third aspect.

According to a sixth aspect, there is provided a method of forming a plasma within a plasma vessel at a predetermined time. The plasma vessel comprises an electron source comprising a filament and a DC biasing means. Prior to the predetermined time, a gas is provided within the plasma vessel at a pressure less than 5×10⁻³ mbar, a DC voltage is applied across the gas, and power is applied to the filament. At the predetermined time, the DC biasing means is used to apply a bias to the filament, causing the electron source to supply electrons to the gas.

According to a seventh aspect, there is provided a system for forming a glow discharge plasma within a plasma vessel. The system comprises a vacuum system, electrodes, an electron source, and a controller. The vacuum system is configured to maintain the pressure of the plasma vessel at less than 5×10⁻³ mbar. The electrodes are configured to provide a DC potential across a gas contained in the plasma vessel. The electron source is configured to provide electrons to the gas. The controller is configured to cause the vacuum system to maintain the pressure of the plasma vessel at less than 5×10⁻³ mbar; and to ignite a glow discharge plasma in the plasma vessel by causing the electrodes to apply the DC voltage and causing the electron source to provide electrons.

According to an eighth aspect, there is provided a plasma vessel comprising an electron source. The electron source comprises a filament, a container, and a mesh. The filament is configured to emit electrons when an electric current is passed through the filament. The container encloses the filament and has an open end and is configured to be biased at a negative voltage. The mesh is located across the open end of the container and is electrically isolated from the container and configured to be grounded.

According to a ninth aspect of the invention, there is provided the use in a spherical tokamak of a plasma having a pressure less than 5×10⁻³ mbar for glow discharge cleaning.

### BRIEF DESCRIPTION OF THE DRAWINGS

FIG. 1A is an illustration of a “high pressure” plasma mode;

FIG. 1B is a graph of intensity along a line through FIG. 1A;

FIG. 2A is an illustration of a “low pressure” plasma mode;

FIG. 2B is a graph of intensity along a line though FIG. 2A;

FIG. 2C is a photograph of the “low pressure” mode;

FIG. 3 is a flowchart of a method of igniting a plasma;

FIG. 4 is a schematic illustration of an electron gun for use in a plasma chamber.

### DETAILED DESCRIPTION

It has been found that the GDC can be operated at surprisingly low pressures, below 5×10⁻³ mbar, without the expected high risk of arcing. This is possible by the plasma forming in a previously unknown low pressure mode. This plasma mode is clearly different to previously known modes (e.g. it appears green, rather than the pinkish colour of typical GDC operation). The optical emission spectrum is dominated by the 501.5 nm helium atomic emission line (the transition from 1s3p¹P₁ to 1s2s ¹S₀).

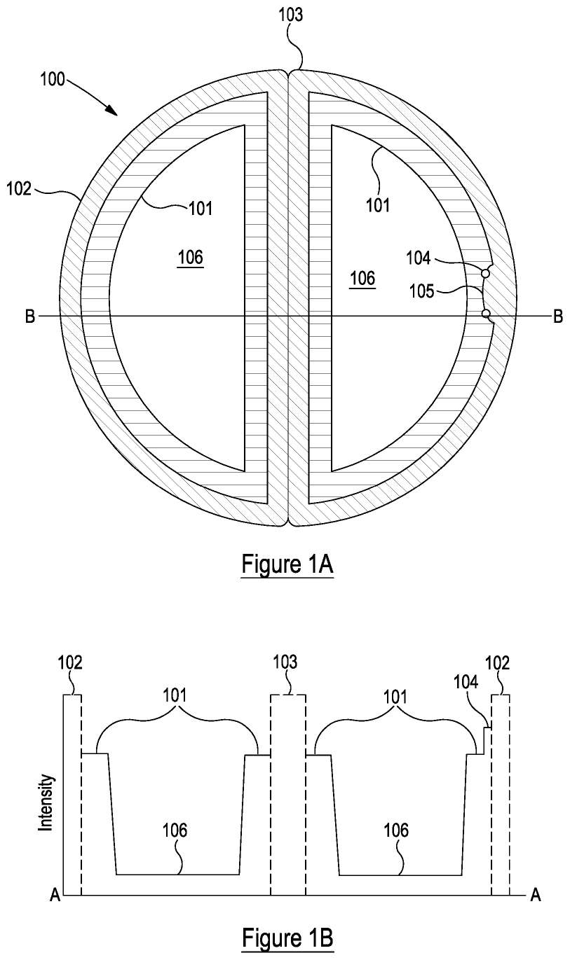

The plasma also has a very different structure in the low pressure mode compared to the conventional high pressure mode. FIG. 1A is an illustration of a plasma in a chamber 100 of a tokamak in the higher pressure mode conventionally used for GDC. The plasma forms “sheaths” 101 around structures in the chamber 100 (such as chamber walls 102 and central column 103), and bright ball-like structures 104 form on the electrode 105. The plasma 106 in the regions of the chamber away from the structures is considerably less bright. As shown in FIG. 1B, which is a graph of intensity along the line B-B of FIG. 1A, this results in regions of the plasma adjacent to chamber structures emitting light at a higher intensity than the rest of the plasma.

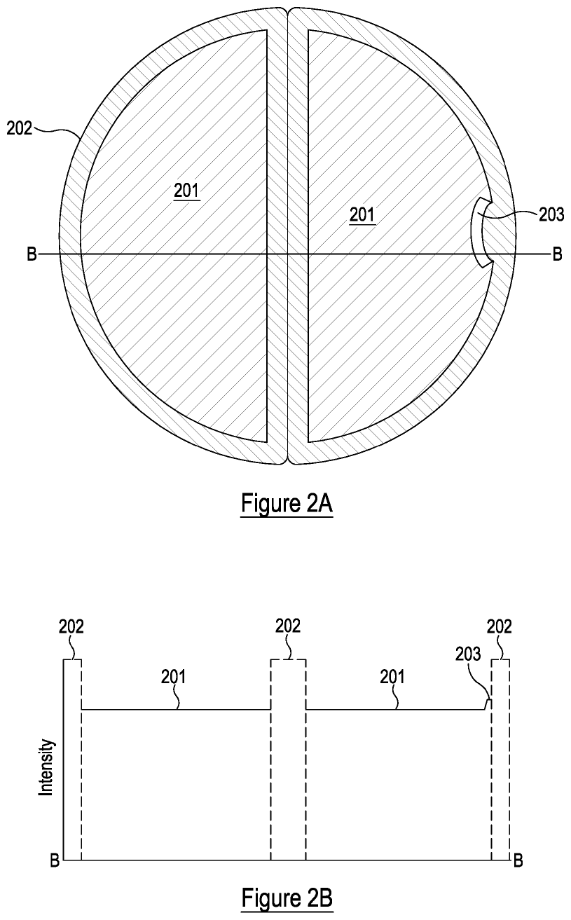

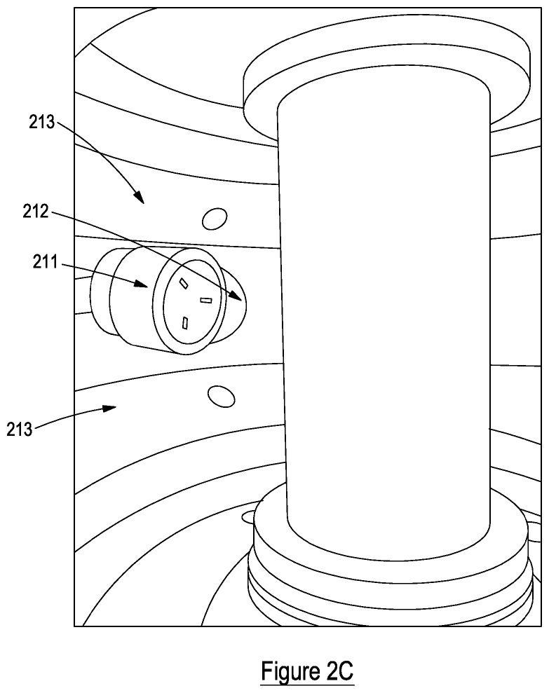

FIG. 2A is an illustration of the low pressure mode plasma 201 within a plasma chamber 202. For the low pressure mode, the plasma sheath on features and structure with in the chamber is absent. There is a more diffuse glow 203 around the electrode. The plasma suffuses the chamber more evenly, and the intensity of emitted light is substantially constant, as shown in FIG. 2B. FIG. 2C is a photograph showing this in practice. The electron source 211 and DC voltage source 212 can be seen, and it will be noted that the plasma (blue glow) suffuses the chamber evenly. A slight glow around the DC voltage source can be seen, though this is somewhat more obvious in the reflections 213 on the chamber wall.

The high pressure mode emits at a variety of wavelengths, corresponding to many different atomic transitions. The spectrum of the low pressure mode is dominated by the 1s3p¹P₁ to 1s2s ¹S₀ transition line at 501.5 nm (301) The low pressure mode is much more stable with much reduced arcing. The optically visible range of this low pressure mode of the plasma extends from approximately 2×10⁻⁴ mbar up to 5×10⁻³ mbar, and it can be ignited at lower pressures (though it will not be visible). However, such plasma modes are not self-starting, but require the injection of electrons into the gas to trigger them.

Typically there is already an electron source in a tokamak reactor to initiate pre-ionisation. The electron source typically comprises a filament (which will generate electrons by thermionic emission when heated) and a means to apply a bias voltage to the filament to expel those electrons into the chamber. This electron source can be used in combination with the DC voltage across the plasma to initiate the low-pressure GDC plasma (though, as described later, improvements to the electron sources typically used can make them more suitable for both pre-ionisation and GDC initiation).

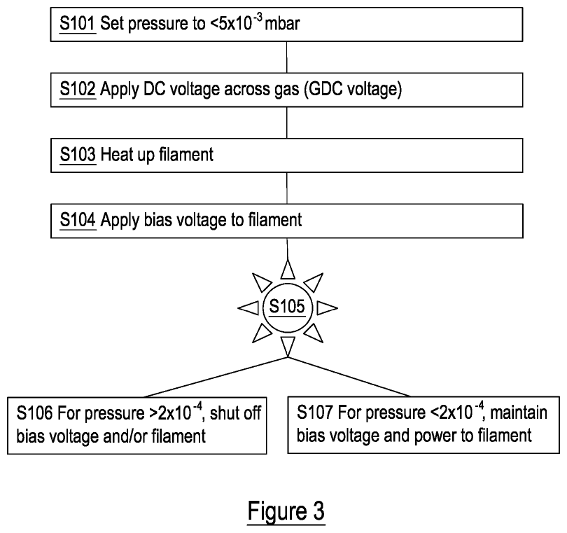

FIG. 3 is a flowchart showing the ignition process for the low pressure mode. In step S101, the pressure of the gas in a plasma chamber is set to less than 5×10⁻³ mbar, e.g. by pumping gas from the chamber. In step S102, a DC voltage is applied across the gas. This voltage is often referred to as the GDC potential or voltage, and may vary from a few volts to a few tens of kilovolts. In step S103, the filament of the electron source is heated up. In step S104, a bias voltage is applied to the filament to expel electrons into the plasma chamber, which causes ignition of the plasma (S105) in a very short time (a few milliseconds). Until the bias voltage is applied, the plasma mode will not ignite from the GDC voltage alone.

Steps S102 and S103 (providing the GDC voltage and heating the filament) may be performed in either order. Step S104 (providing the bias voltage to the electron source) may be provided in any order with steps S102 and S103, but this makes the ignition of the plasma less predictable as it will no longer ignite immediately when the bias voltage is applied.

At pressures between about 2×10⁻⁴ and 5×10⁻³ mbar, the plasma does not require further electrons to be injected once ignited but will continue to run on the power supplied by the GDC electrodes, so the bias voltage and filament may be shut off (S106). At lower pressures (at least as low as 10⁻⁶ bar) the plasma may be maintained by the continuous injection of electrons (S107) but a visible glow is no longer observable. Additionally, if electrons additional to any required to sustain the plasma are injected into a plasma in the low pressure mode, the plasma current is enhanced, producing improved cleaning rates.

The fact that the mode is not self-starting allows the GDC to be started “on-demand”, i.e. at a specific time, much more easily than at higher pressures. The GDC voltage can be applied to the plasma, and power supplied to the filament, but the GDC plasma will not initiate until the filament is biased, sending electrons into the plasma chamber. When that occurs, the initiation is very fast (nearly instantaneous).

Since the trigger for initiation is easily controllable, GDC operation can be automated. For example, the GDC process can be configured such that, if the plasma is extinguished by an arc, then the plasma will be automatically restarted and allowed to continue until the GDC is completed (typically 100 to 150 hours). The re-ignition is as simple as applying a bias to the electron generating filament, which is considerably easier than the startup procedures required for a conventional high pressure GDC plasma.

The low pressure plasma can also be used in place of electrons during pre-ionisation. Rather than supplying electrons into a gas prior to applying the magnetic field, a low-pressure glow discharge can be excited just before the magnetic field is applied. This results in a higher concentration of charged particles than standard pre-ionisation, meaning more charged particles for the magnetic field to accelerate, as a result of which a more energetic plasma is formed. Simple biased filaments are able to provide from a few millamps to 100 mA or so while electron guns can deliver many amps.

The ability to start the glow discharge on-demand for the low pressure mode enables the glow discharge to be activated at exactly the right point of the pulse sequence —maximising the effect of the glow discharge pre-ionisation. For example, in many pulse sequences, ignition is required not on the upswing of the current and magnetic field in the plasma ignition coils, but rather on the downswing when the rate of change of current in the coils, dl/dt, and hence field, is greatest. Premature ignition during the upswing reduces the achievable plasma current and so ignition timing is critical.

The low pressure plasma mode may be operated below 5×10⁻³ mbar, below 10⁻³ mbar, and/or below 5×10⁻⁴ mbar. With the continued addition of electrons to the plasma during operation, it may be operated below 2×10⁻⁴ mbar, below 10⁻⁴ mbar, below 10⁻⁵ mbar.

To assist with providing electrons for either glow discharge or conventional pre-ionisation, an improved electron source can be provided. As noted above, previously known plasma vessels typically use a hot filament with a negative bias. Several improvements are possible by switching to an “electron gun” configuration where the electrons are accelerated towards the target plasma, reducing the proportion that are lost to ground onto other surfaces within the plasma vessel.

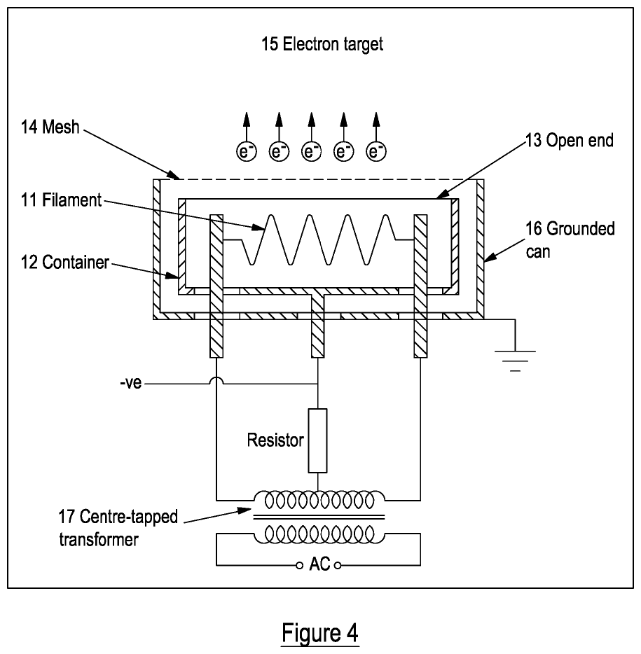

An exemplary electron gun configuration is shown in FIG. 4.

The electron gun comprises a thermionic filament 11, which can be heated and biased negatively to emit electrons. The filament is located within a container 12, which is open at one end 13, and the container 12 can be negatively biased with respected to the filament and to ground. A grounded high-transparency mesh, 14 is located at the open end and electrically isolated from the container. The open end 13 of the container points towards the target location 15 for the electrons. The entire gun is contained in a grounded cylinder 16 to protect it from plasma sputtering. The filament is supplied from a centre-tapped transformer 17. Biasing of the container 12 may be made with a separate supply or by auto-biasing with a resistor.

Electrons are accelerated from the filament towards the grounded mesh by the electric field formed between the negatively biased filament and container and the grounded mesh. Some electrons will ground on the mesh, but most will pass through towards the target location, in this case the gas volume for glow discharge or pre-ionisation.

The filament may be a dispenser cathode. Dispenser cathodes may be formed from barium impregnated tungsten, which has a lower operating temperature than conventional tungsten cathodes for a similar electron emission current. Lower filament temperature results in reduced heating of surrounding components and reduced outgassing. Additionally, any evaporated material from such a dispenser cathode is primarily barium, rather than tungsten. As barium is a lighter element than tungsten, it is a less problematic contaminant of the plasma.

1. A helium plasma characterised by an emission spectrum dominated by the 1s3p ¹P₁ to 1s2s ¹S₀ 501.5 nm transmission line, and a pressure less than 5×10⁻³ mbar.

2. A helium plasma according to claim 1, wherein the pressure is less than 10⁻³ mbar, or less than 5×10⁻⁴ mbar.

3. A plasma vessel comprising:
a DC voltage source configured to provide a voltage across a plasma within the chamber;
a vacuum system configured to maintain the pressure of the interior of the plasma vessel at less than 5×10⁻³ mbar;
a helium plasma according to claim 1.

4. A plasma vessel according to claim 3, wherein the pressure of the plasma is less than 2×10⁻⁴ mbar, the plasma vessel comprising an electron source configured to supply electrons to a plasma within the chamber.

5. A plasma vessel according to claim 3, and comprising an electron source, the electron source comprising:
a filament configured to emit electrons when an electric current is passed through the filament;
a container enclosing the filament and having an open end and configured to be biased at a negative voltage;
a mesh located across the open end of the container and electrically isolated from the container and configured to be grounded.

6. A method of forming a glow discharge plasma within a plasma vessel, the method comprising:
providing a gas within the plasma vessel at a pressure less than 5×10⁻³ mbar;
forming a glow discharge plasma from the gas by:
applying a DC potential across the gas and
using an electron source to supply electrons to the gas.

7. A method according to claim 6, wherein the gas is helium and the plasma is characterised by an emission spectrum dominated by the 1s2p ¹P₁ to 1s2s ¹S₀ 501.5 nm transmission line.

8. (canceled)

9. A method according to claim 6, wherein the electron source comprises a filament, and supplying electrons to the gas comprises providing a negative bias voltage to the filament.

10. A method according to claim 9, wherein the filament is a barium impregnated dispenser cathode.

11. A method of glow discharge cleaning a plasma vessel, the method comprising forming a glow discharge plasma within the plasma vessel by the method of claim 6, and maintaining the DC voltage for a duration of the cleaning.

12. A method according to claim 11, and comprising reducing or ceasing the supply of electrons to the plasma following ignition of the plasma.

13. A method according to claim 12, and comprising:
detecting the extinguishing of the glow discharge plasma;
in response to said extinction, re-forming the glow discharge plasma by restarting or increasing the supply of electrons to the gas.

14. A method according to claim 11, and comprising supplying electrons to the glow discharge plasma for the duration of the cleaning.

15. A method of pre-ionisation in a fusion reactor comprising a plasma vessel, the method comprising:
forming a glow discharge plasma in the plasma vessel by the method claim 6.

16. A method of forming a plasma within a plasma vessel at a predetermined time, the plasma vessel comprising an electron source comprising a filament and a DC biasing means, the method comprising:
prior to the predetermined time:
providing a gas within the plasma vessel at a pressure less than 5×10³ mbar;
applying a DC voltage across the gas;
applying power to the filament;
at the predetermined time, using the DC biasing means to apply a bias to the filament, causing the electron source to supply electrons to the gas.

17. A method
according to claim 16, wherein the gas is helium the plasma is characterised by an emission spectrum dominated by the 1s2p ¹P₁ to 1s2s ¹S₀ 501.5 nm transmission line

18. (canceled)

19. A system for forming a glow discharge plasma within a plasma vessel, the system comprising:
a vacuum system configured to maintain the pressure of the plasma vessel at less than 5×10⁻³ mbar;
electrodes configured to provide a DC potential across a gas contained in the plasma vessel;
an electron source configured to provide electrons to the gas; and
a controller configured to:
cause the vacuum system to maintain the pressure of the plasma vessel at less than 5×10⁻³ mbar; and
ignite a glow discharge plasma in the plasma vessel by:
causing the electrodes to apply the DC voltage; and
causing the electron source to provide electrons.

20. A system
according to claim 19, wherein the gas is helium and the plasma is characterised by an emission spectrum dominated by the 1s2p ¹P₁ to 1s2s ¹S₀ 501.5 nm transmission line.

21-25. (canceled)

26. Use in a spherical tokamak of a plasma having a pressure less than 5×10⁻³ mbar for glow discharge cleaning.

27. Use in a spherical tokamak of a plasma according to claim 1 for glow discharge cleaning.
